(19) United States
(12) Patent Application Publication
(10) Pub. No.: US 2009/0115436 A1
(43) Pub. Date: May 7, 2009

(54) Methods for Determining Fluid Properties

(76) Inventors: Charles J. Koehler, III, Milwaukee, WI (US); Richard W. Hirthe, Milwaukee, WI (US)

Correspondence Address: WHYTE HIRSCHBOECK DUDEK S.C.;INTELLECTUAL PROPERTY DEPARTMENT, 33 East Main Street, Suite 300, Madison, WI, 53703-4655, US

(21) Appl. No.: 12/263,046

(22) Filed: Oct. 31, 2008

Related U.S. Application Data
(60) Provisional application No. 60/985,120, filed on Nov. 2, 2007.
(60) Provisional application No. 60/985,127, filed on Nov. 2, 2007.
(60) Provisional application No. 60/985,134, filed on Nov. 2, 2007.

(51) Int. Cl. G01R 27/08

(52) U.S. Cl. 324/698

(57) ABSTRACT

Disclosed herein is a method for determining two or more properties of a blended biofuel fluid sample, the method comprising measuring a complex impedance of the sample at each of a plurality of frequencies to produce a sample data set, determining a biofuel blend percentage of the sample using the sample data set; and determining at least one additional property of the sample based upon the determined biofuel blend percentage. In another aspect, a biofuel blend percentage of the sample can be determined using an algorithm developed using a data gathering and data mining technique relating measured impedance spectroscopy data from a plurality of samples to biofuel blend percentage values determined using a standard analytical measuring method for biofuel blend percentages.

### CROSS-REFERENCE TO RELATED APPLICATIONS

This application claims priority to U.S. provisional patent application Ser. Nos. 60/985,120; 60/985,127, and 60/985,134, all filed on Nov. 2, 2007.

### FIELD OF THE INVENTION

The present invention relates to methods and systems for analyzing fluids such as blended biofuels using impedance spectroscopy (IS) and for determining one or more fluid properties.

### BACKGROUND OF THE INVENTION

Increasing consumption of fossil fuels is occurring on a worldwide basis. Many countries rely on fossil fuel use to the detriment of society and ecosystems. Reduction in the amount of fossil fuel consumption and increased use of bio-based fuels has become an increasingly important initiative for consumers and governments alike. In particular, the increased use of biodiesel is lauded as an important step in the direction of reducing fossil fuel consumption. However, the transition to including biodiesel in everyday fuel has created a series of problems to both diesel consumers and combustion engine manufacturers. A key problem surrounds determining the concentration of biofuel, often referred to as fatty acid methyl ester (FAME), within a blended biodiesel/diesel sample. Identification of other alkyl esters is contemplated by this invention.

Biodiesel is often defined as the monoalkyl esters of fatty acids from vegetable oils and animal fats. Neat and blended with conventional petroleum diesel fuel, biodiesel has seen significant use as an alternative diesel fuel. Biodiesel is often obtained from the neat vegetable oil transesterification with an alcohol, usually methanol (other short carbon atom chain alcohols may be used), in the presence if a catalyst, often a base. Various unwanted materials are found in biodiesel, which can include glycerol, residual alcohol, moisture, unreacted feedstock (triacylglycerides), monglycerides, diglycerides, and free (unreacted) fatty acids.

Biodiesel fuels are often blended compositions of diesel fuel and biomass, which is often esterified soy-bean oils, rapeseed oils or various other vegetable oils. It is the similar physical and combustible properties to diesel fuel that has allowed the development of biofuels as an energy source for combustion engines. However, biofuels are not a perfect replacement for diesel. By example, the conversion quality, oxidation stability and corrosion potential of these biofuels present a concern to continued consumption as a viable fuel. Based upon these issues, as well as others known to one skilled in the art, careful control of the biofuel properties must be implemented.

Beyond the physical and chemical concerns, monetary concerns exist. The United States government provides a tax credit for biofuel consumption. The tax credit is based upon the biofuel percentage within a biodiesel blend. In fact, the tax credit can be substantially different for a slight change in the percentage, since $0.01 per FAME percentage per gallon used is provided by the government. Therefore the difference between 20% and 25% FAME in—biodiesel fuel can result in a considerable tax value. Often it is the case that biodiesel blends are “splash-blended”, which refers to the liquid agitation that occurs as the fuel truck is driving on the road after the diesel and biofuel have been combined. “Splash-blended” biodiesel blends often have a blend variance of up to 5%, which is unacceptable.

Various methods and technologies have been employed to determine the biofuel percentage within a biodiesel blend. These methods include gas chromatography (GC), fourier transform infrared (FTIR) spectroscopy, and near-infrared (NIR) spectroscopy. None of these methods provide a portable, quick and accurate determination of the FAME percentage within a biodiesel blend.

It would be advantageous to have a system and method for quickly and accurately determining the concentration of biodiesel fuel blends for use in quality control, production testing and distribution testing.

### BRIEF DESCRIPTION OF THE DRAWINGS

FIG. 1 is a block diagram of the fuel analyzer system in accordance with at least one embodiment of the invention;

FIG. 2 is a block diagram of a logic controller in accordance with at least one embodiment of the invention;

FIG. 3 is an alternative embodiment of the fuel analyzer system in accordance with at least one embodiment of the invention;

FIG. 4 is a flow chart representing a method for analyzing biodiesel blends in accordance with at least one embodiment of the invention;

FIG. 5 is a FTIR spectra for biodiesel concentration;

FIG. 6 is a Beer's Law FTIR model for biodiesel concentration standards;

FIG. 7 is a room temperature impedance spectra for biodiesel standards;

FIG. 8 is an impedance spectroscopy model for biodiesel concentration standards;

FIG. 9 is a test data table including both FTIR and impedance spectroscopy data;

FIG. 10 is a biodiesel method comparison data plot;

FIG. 11 is a biodiesel method residuals data plot;

FIG. 12 is an alternative embodiment of the impedance spectroscopy data analyzer in accordance with at least one embodiment of the present invention;

FIG. 13 is a measured form calculation sequence;

FIG. 14 is a Complex Plane Representation mathematical sequence;

FIG. 15 is an impedance and modulus plot sequence;

FIG. 16 is a biodiesel modulus spectra plot;

FIG. 17 is an impedance spectroscopy derived model data plot;

FIG. 18 is a block and wiring diagram of an exemplary hand-held analyzer device, in accordance with at least some embodiments of the present invention;

FIG. 19 is a partially exploded front perspective view of the exemplary hand-held analyzer device illustrated in block diagram form in FIG. 18, in accordance with at least some embodiments of the invention;

FIG. 20 is a perspective view of an exemplary sample cell, in accordance with at least some embodiments of the present invention;

FIG. 21 is a flow chart illustrating an example of operation of the hand-held device, in accordance with at least some embodiments of the present invention;

FIG. 22 is a flow chart illustrating an example method for data gathering and data mining to produce an algorithm for determining a desired fluid property using impedance spectroscopy;

FIG. 23 is a graph showing a GMDH-derived correlation between IS predicted and reference analytical standard values for blend concentration;

FIG. 24 is a graph showing a GMDH-derived correlation between IS predicted and reference analytical standard values for total glycerin concentration for B100 fuels;

FIG. 25 is a graph showing a GMDH-derived correlation between IS predicted and reference analytical standard values for total glycerin concentration for Bxx fuels;

FIG. 26 is a graph showing a GMDH-derived correlation between IS predicted and reference analytical standard values for acid number for B100 fuels; and

FIG. 27 is a graph showing a GMDH-derived correlation between IS predicted and reference analytical standard values for methanol content for B100 fuels.

### DETAILED DESCRIPTION

Biodiesel includes fuels comprised of short chain, mono-alkyl, preferably methyl, esters of long chain fatty acids derived from vegetable oils or animal fats. Short carbon atom chain alkyl esters have from e.g., 1 to 6 carbon atoms, preferably 1 to 4 carbon atoms and most preferably 1 to 3 carbon atoms. Biodiesel is also identified as B100, the “110” representing that 100% of the content is biodiesel. Biodiesel blends include a combination of both petroleum-based diesel fuel and biodiesel fuel. Typical biodiesel blends include B5 and B20, which are 5% and 20% biodiesel respectively. Diesel fuel is often defined as a middle petroleum distillate fuel.

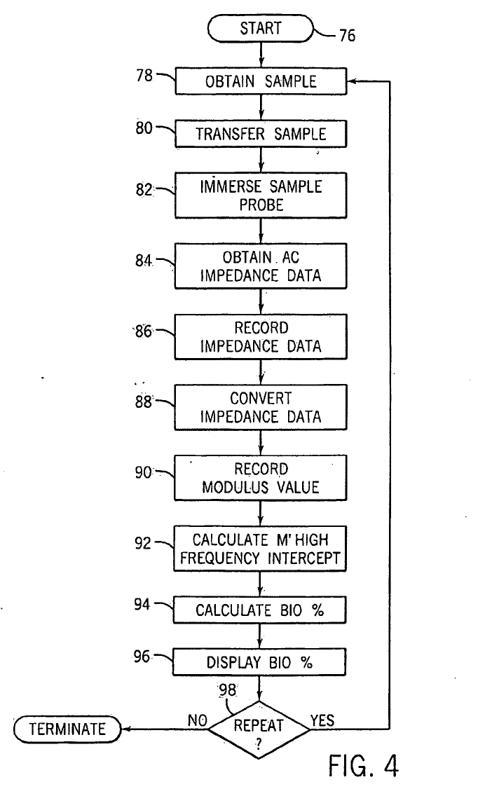

Now referring to FIG. 1, an illustrative example of the system 10 in accordance with at least one embodiment of the invention includes an analysis device 12, graphical user interface (GUI) 14, memory storage device 16, probe 18, and reservoir 20. The analysis device 12 includes a logic controller 22, a memory storage device 24, a modulus converter 26 and an impedance converter 28. The reservoir 20 contains a biofuel sample, which can be selected from the group including a biodiesel blend, heating fuel, second phase materials, fuel additives, methanol, glycerol, residual alcohol, moisture, unreacted feedstock (triacylglycerides), monoglycerides, diglycerides, and free (unreacted) fatty acids. The probe 18 is external and separately connected to the reservoir 20 and can alternatively be integrated within the reservoir 20. The probe 18 provides inputs to the reservoir 20 through input/output line 30. Excitation voltage (V_{(f)}) is applied to the reservoir from probe 18 and a response current (I_{(f)}) over a range of frequencies is measured and provided to the analysis device 12. The impedance data is analyzed and converted by the impedance converter 28, and then transferred to the modulus converter 26. The impedance data includes Zᵣₑₐₗ, Z_{imaginary}, and frequency. The modulus data includes Mᵣₑₐₗ, M_{imaginary}, and frequency. The logic controller 22 operates the modulus converter 26 and impedance converter 28 to store the respective data, including the impedance measurements, within memory storage device 24. The logic controller performs a computer readable function, which is accessed from memory storage device 24 that performs an impedance spectroscopy analysis method (See FIG. 4) and provides a biodiesel concentration to the GUI 14. The concentration data can be provided in the form of Bxx, where “xx” represents the concentration of the sample tested that is biofuel (biomass/FAME) in percentage of biodiesel. Concentration and percentage are often used interchangeably to describe the amount of biodiesel within a blended sample.

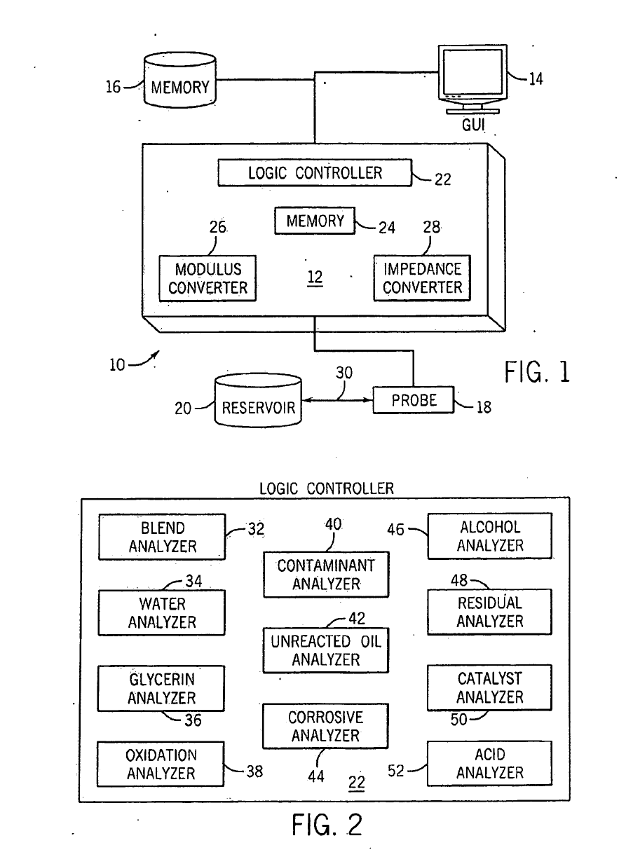

Referring to FIG. 2, an alternative embodiment of the logic controller 22 is illustrated. The logic controller 22 includes a blend concentration analyzer 32, a water analyzer 34, a glycerin analyzer 36, an oxidation analyzer 38, a contaminant analyzer 40, and unreacted oil analyzer 42, a corrosive analyzer 44, an alcohol analyzer 46, a residual process chemistry analyzer 48, a catalyst analyzer 50, and a total acid number analyzer 52. The water analyzer 34 performs analysis on the impedance data obtained from probe 18. The logic controller 22 accesses a computer readable function accessed from memory storage device 24 and provides information such as the presence of water, and if identified within the sample, the concentration of water within the sample. The glycerin analyzer 36 performs analysis on the impedance data obtained from probe 18. The logic controller 22 accesses a computer readable function accessed from memory storage device 24 and provides information such as the presence of glycerin, and if identified within the sample, the concentration of glycerin within the sample. Alternatively, the computer readable function is accessed from memory 16. In an alternative embodiment, a viscosity analyzer (not shown), and cetane number analyzer (not shown) are included for providing viscosity data and cetane number data for a fuel sample. In yet another alternative embodiment, a sludge/wax analyzer (not shown) are included for providing information on the presence and amount of sludge and/or wax precipitation within a fuel sample.

The oxidation analyzer 38 performs analysis on the impedance data obtained from probe 18. The logic controller 22 accesses a computer readable function accessed from memory storage device 24 and provides information such as the presence of oxidation. The contaminant analyzer 40 performs analysis on the impedance data obtained from probe 18. The logic controller 22 accesses a computer readable function accessed from memory storage device 24 and provides information such as the presence of contaminants, and identification of the type of contaminants within the sample, as well as the concentration of the particular contaminant within the sample. A variety of contaminants can be found within fuel samples, which include water, wax/sludge, and residual process chemistry.

The unreacted oil analyzer 42 performs analysis on the impedance data obtained from probe 18. The logic controller 22 accesses a computer readable function from memory storage device 24 and provides information such as the presence of unreacted oils, as well as the concentration within the sample. A variety of unreacted oil can be found within fuel samples, which include unreacted feedstock (triacylglycerides), monoglycerides, diglycerides, and free (unreacted) fatty acids.

The corrosive analyzer 44 performs analysis on the impedance data obtained from probe 18. The logic controller 22 accesses a computer readable function from memory storage device 24 and provides information such as the presence of corrosives, as well as the reactivity of the corrosive substances within the sample.

The alcohol analyzer 46 performs analysis on the impedance data obtained from probe 18. The logic controller 22 accesses a computer readable function from memory storage device 24 and provides information such as the presence of alcohol, and if present, the concentration of alcohol within the sample. The residual analyzer 48 performs analysis on the impedance data obtained from probe 18. The logic controller 22 accesses a computer readable function memory storage device 24 and provides information such as the presence of residuals, and identification of the type of residuals within the sample, as well as the concentration of the residuals within the sample. A variety of residuals can be found within fuel samples, which include alcohol, catalyst, glycerin and unreacted oil.

The catalyst analyzer 50 performs analysis on the impedance data obtained from probe 18. The logic controller 22 accesses a computer readable function from memory storage device 24 and provides information such as the presence of catalysts, as well as the concentration of the catalysts within the sample. A variety of catalysts can be found within fuel samples, which include KOH and NaOH. The total acid number analyzer 52 performs analysis on the impedance data obtained from probe 18. The logic controller 22 accesses a computer readable function from memory storage device 24 and provides information such as the presence of acids, as well as the concentration of the acids within the sample. A variety of acids can be found within fuel samples, which include carboxylic acid and sulfuric acid.

In an alternative embodiment, a stability analyzer (not shown) is provided. The stability analyzer performs analysis on the impedance data obtained from probe 18. The logic controller 22 accesses a computer readable function accessed from memory storage device 24 and provides information such as a stability value. Recent research has found that changes to the biodiesel element of biodiesel blends can have a deleterious effect upon the stability of the fuel sample over time. Blended samples that are left inactive for extended periods of time can potentially lose stability. The impedance spectroscopy data and stability analyzer function of this invention can provide information as to the sample's stability and efficacy.

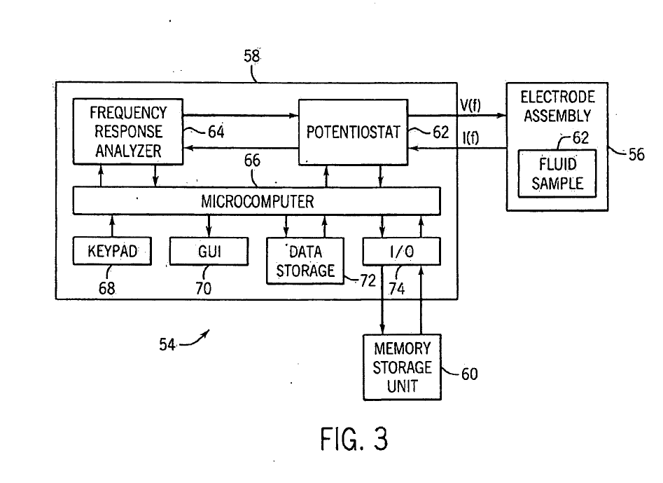

Referring to FIG. 3, an alternative embodiment of the impedance spectroscopy analyzing system 54, which includes an electrode assembly 56, a data analyzer 58, and a memory storage unit 60 is provided. The electrode assembly 56 includes a fluid sample 62 and probes (not shown). The data analyzer 58 includes a potentiostat 63, a frequency response analyzer 64, a microcomputer 66, a keypad 68, a GUI (graphical user interface) 70, data storage device 72, and U/O device 74. Impedance data is obtained from the electrode assembly 56 and input into the analyzer 58. The potentiostat 63 and frequency response analyzer together perform the impedance spectroscopy analysis methods (See FIG. 4). The microcomputer 66 accesses the computer readable functions from the memory storage unit 60 or the data storage device 72, and provide biofuel analyzed data to the GUI 70

Referring to FIG. 4, a flow chart is provided representing a method for determining the concentration of biodiesel (e.g., biomass/FAME content) in a blended biodiesel fuel sample in accordance with at least one embodiment of the present invention. The system 10 is initiated at step 76. A sample of the blended biodiesel is obtained at step 78 and then transferred to a clean container or reservoir at step 80. The sample is maintained at substantially room temperature, generally between about 60° F. and about 85° F. Alternatively, the sample is located in a vehicle fuel tank on board a vehicle or deployed “in-line” e.g., in a biodiesel synthesis plant. Measurement probes are cleaned and imniersed within the reservoir at step 82. Alternatively, probes can be maintained within the reservoir and the fuel sample is added to the reservoir with the probes already within the reservoir. The probes can be self-cleaning probes. The impedance device is initiated and the AC impedance characteristics of the fuel sample are obtained at step 84. The frequency range extends from about 10 milliHertz to about 100 kHertz, or alternatively appropriate frequencies. The impedance data is recorded at step 86. The data can be saved in a memory device integral to the device 12. Alternatively, the impedance data is saved in an external memory device. The external memory device 16 can be a relational database or a computer memory module. At step 88, the impedance data is converted to complex modulus values. The complex modulus values are recorded at step 90. M′ high frequency intercept values are determined at step 92 from the complex modulus values and the biodiesel concentration is calculated at step 94. By example, Equation Set 1 is a linear algorithm used for calculating the biodiesel blend concentration. The biodiesel concentration value is represented on a user interface at step 96. If the process continues step 78 is repeated at 98, otherwise the sequence is terminated at step 100. One skilled in the art would recognize that there are chemical differences between biodiesel and petroleum-based diesel for which the present invention can be employed.

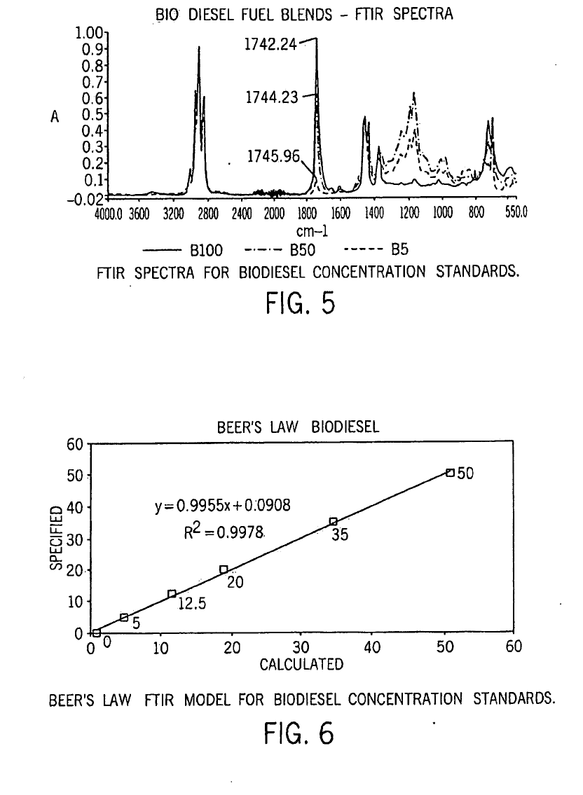

The Fourier transform infrared (FTIR) spectra analysis of three biodiesel concentration is provided in FIG. 5. Samples of B100, B50, and B5 were tested using an FTIR process. The FTIR process used for data obtained in FIG. 5 was modeled after the AFNOR NF EN 14078 (July 2004) method, titled “Liquid petroleum products—Determination of fatty acid methyl esters (FAME) in middle distillates—Infrared spectroscopy method.” Biodiesel fuel samples were diluted in cyclohexane to a final analysis concentration of about 0% to about 1.14% biofuel. This was to produce a carbonyl peak intensity that ranged between about 0.1 to about 1.1 Abs, using a 0.5 mm cell pathlength. The method showed a 44 g/l sample (B5 sample was diluted to 0.5%) having 0.5 Abs carbonyl peak height. The method recommended 5-standards be prepared ranging from about 1 g/l (about 0.11% biofuel) to about 10 g/l (about 1.14% biofuel).

The peak height of the carbonyl peak at or near 1245 cm⁻¹ was measured to a baseline drawn between about 1820 cm⁻¹ to about 1670 cm⁻¹. This peak height was used with a Beer's Law plot of absorbance versus concentration to develop a calibration curve for unknown calculation.

The modifications made to this method included no sample dilution, an AIR cell and utilization of peak area calculations. Sample dilution with cyclohexane is a very large source of errors. The reasons to dilute the sample include reducing the viscosity for flow (transmission cell), opacity or to maintain the absorption peak height of the sample with the detector linearity. The detector linearity of the instrument used was in the range of about 0 Abs to about 2.0 Abs. By reducing the cell pathlength to about 0.018 mm the absorbance of a B100 sample was about 1.0 Abs. This allowed dilution to be unnecessary. The use of a UATR cell allowed a very controlled and fixed pathlength to be maintained.

The peak of interest demonstrated migration during dilution due to solvent interaction, evidenced in the biofuel spectra shown in FIG. 5. As a result, the peak area was chosen as the measurement technique. In addition, peak area is the preferred technique for samples that contain multiple types of a defined chemistry type, such as that found in biofuels. Substances found in biofuels that are distinguishable from one another and from petroleum-based fuels constituents by means of impedance spectroscopy are, of course, a focus of this invention. Exemplary substances include saturated and unsaturated esters. The result of Beer's law calibration is shown in FIG. 6. The biofuel samples were measured against the calibration curve of FIG. 6. The impedance spectroscopy methods were measured against this FTIR process.

y=−3.371E+07x−8.158E+09 Equation Set 1
where y=M′ and x=% biodiesel

At least one embodiment of the present invention was tested for feasibility by comparison with FTIR analysis, an industry accepted test method, of biodiesel fuel blend concentration. The blend samples that were tested included B50, B20 and B5. The samples were evaluated using both broad spectrum AC impedance spectroscopy as well as FTIR spectroscopy. Additionally, the blends of unknown values were tested to determine the impedance data using impedance spectroscopy. Conventional diesel fuel and a variety of nominal blend ratios were used as test standards.

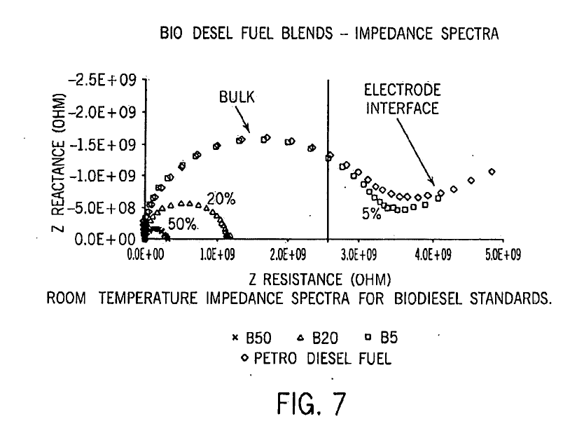

Approximately 20 mL samples of each biodiesel blend were evaluated at room temperature utilizing a two (2) probe measurement configuration. FIG. 7 provides an example of the impedance spectra in a line plot configuration, with reactance (ohm) plotted against resistance (ohm). The impedance spectra provide a clear distinction between B50, B20, B5, and petroleum diesel fuel. Generally the impedance at given frequency, ω, contains two contributions as shown in Equation Set 2. More specifically, FIG. 7 provides the resistance (Rₛ) plotted against the Reactance (1/ωCₛ), which provides an indication that the resistivity of the biodiesel blend sample is sensitive to the percent biodiesel within the base diesel fuel. As a result, the impedance spectra can be used to identify the concentration percentage of biodiesel within a biodiesel blend sample.

Z*(ω)=Rₛ−j(1/ωCₛ) Equation Set 2

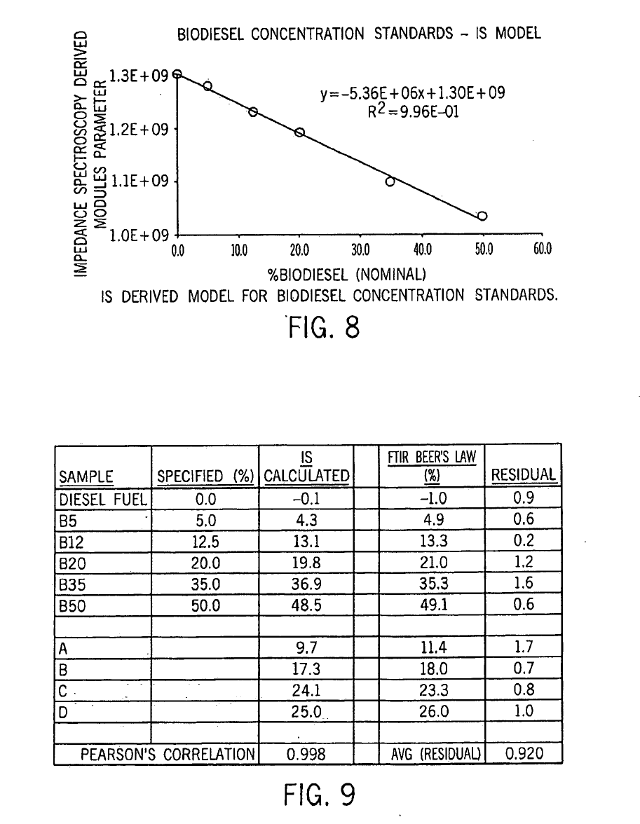

Further manipulation of the impedance data indicates that the polarizability of the blended biodiesel sample is systematically impacted as the concentration of biodiesel increases or decreases. Therefore, a real modulus representation value can be calculated. This presents a parameter, for which a correlation can be made. A correlation between the measured impedance-derived spectra data and the stated biodiesel percentage concentration value can be established. The correlation is graphically presented in FIG. 8, where the impedance derived modulus parameter is plotted against the biodiesel concentration. A linear relationship having a negative slope is provided. These results provide an indication that a correlation similar to that of the industry accepted FTIR method is feasible for impedance spectroscopy.

Referring to FIG. 9, a test data table is provided. The table includes known biodiesel standards, including pure petroleum diesel fuel, B5, B12, B20, B35, and B50. Each of these standards (Reference Standards) was tested using the FTIR process and the impedance spectroscopy process of the present embodiment. The results for each of these tests are provided in the table. Additionally there are four unknowns, A, B, C, and D (Unknown Blend Set 1), for which test results were obtained using both the FTIR process and the impedance spectroscopy process of the present embodiment.

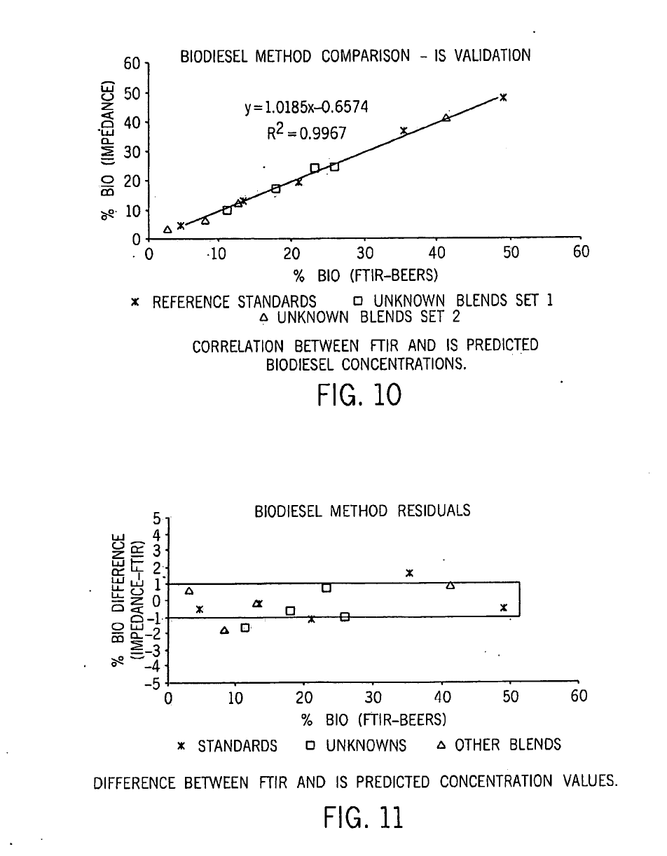

Referring to FIG. 10, the test data provided in FIG. 9 is presented in the form of a X-Y plot. The biodiesel concentration data obtained from the impedance spectroscopy process is plotted against the biodiesel concentration data obtained from the FTIR process. A correlation line is fit to the data points, which indicates a close correlation between the two methods for determining biodiesel concentration. Additionally, a second set of unknown biodiesel blends (Unknown Blends Set 2) were tested through both stated processes. These unknown blends were prepared by blending B100 and two separate petroleum fuels. These data points are not provided in FIG. 9, but are plotted in FIG. 10.

A scientifically significant agreement between the FTIR process and the impedance spectroscopy process of the present embodiment was found. This is evidenced by the line fit assigned to the plotted data points. Residual values (% bio_{FTIR}−% bio_{Impedance}) were calculated and provided in FIG. 9. The average residual value is 0.920, which is less than 1.0%, presenting a highly significant linear correlation between the widely accepted FTIR process and the impedance spectroscopy process of the present embodiment. The difference between the FTIR process and the impedance spectroscopy process of the present embodiment are presented in FIG. 11.

The system 10 can be implemented in the form of a low cost, portable device for determining real-time evaluation of biodiesel blends. The device provides the user with blended FAME concentration in order for the user to compare with established specifications. Furthermore, the device enables the user to detect contaminants and unwanted materials within the biodiesel sample. The impedance spectroscopy data processing provides the user a broader functionality view of the biodiesel sample, and not simply the chemical make-up. Performance of the fuel can be affected by unwanted materials and by detecting the presence of the unwanted materials the user is better able to make decisions that affect performance of the vehicle.

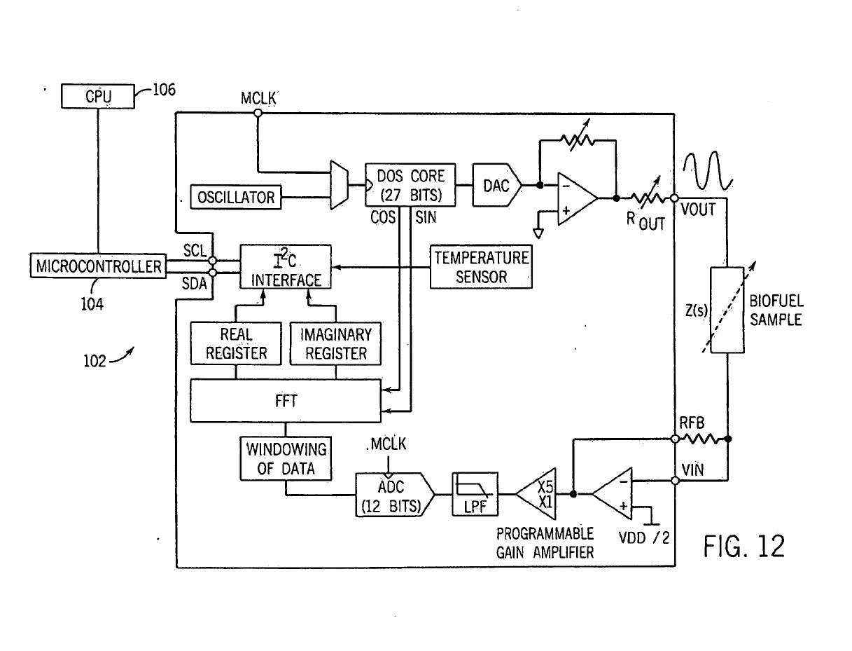

Another embodiment of the impedance spectroscopy system is shown in FIG. 12, which illustrates in block diagram form a portable, bench-top device 102. The biofuel sample can be tested external to the device 102, or alternatively internal to the device 102. A microcontroller 104 relays data to the central processing unit (CPU) 106 for calculation. Once the data has been calculated the biofuel concentration is sent to a graphical user interface (GUI) (not shown) by an I/O device (not shown). The device 102 has either an internal or external power source, as well as a suitable sampling fixture. The impedance data is acquired by the device 102 and transferred to the CPU for detection and identification, of elements within the sample as well as the relative concentrations of the elements. By example, the elements can include FAME, glycerol, residual alcohol, moisture, additives, corrosive compounds, unreacted feedstock (triacylglycerides), monglycerides, diglycerides, and free (unreacted) fatty acids.

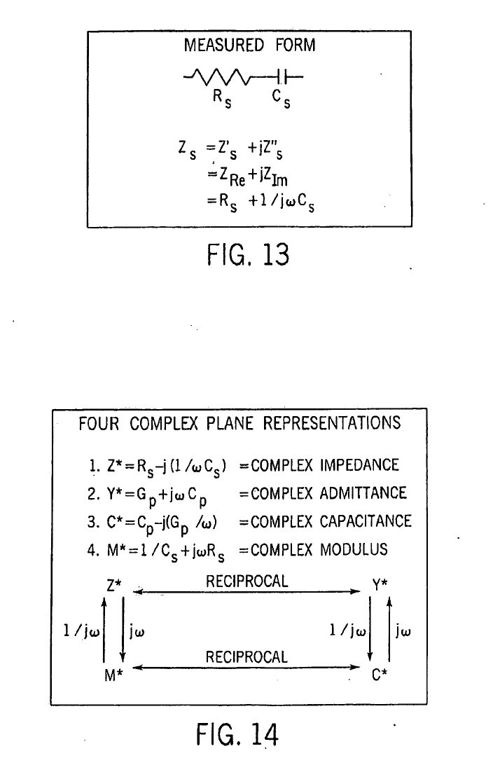

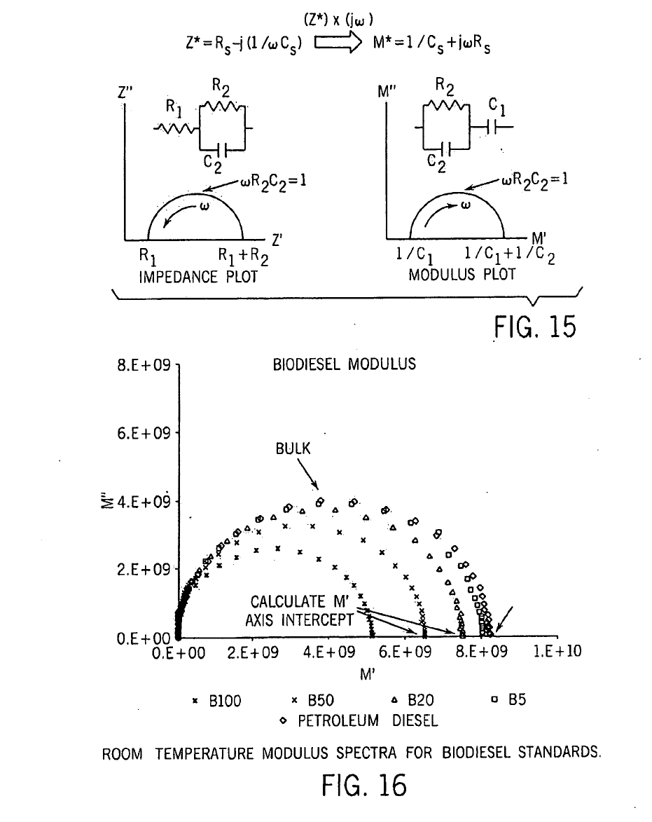

The biodiesel blend sample is tested and data is acquired by treating the sample as a series R—C combination. (See FIG. 13). The acquired sample data is converted by inversion of the weighting of the bulk media contribution to the total measured data response, wherein the value C₂ is typically a small value (See FIG. 14). This conversion minimizes the interfacial contribution of the bulk media, wherein the value C₁ is typically a large value (See FIG. 15). The real modulus transformation (M′) calculated for each biofuel sample is divided by the value (2*PI) in order to disguise the identity.

The biodiesel modulus spectra for the dedicated testing standards are provided in FIG. 16. The modulus data element M″ is plotted against the modulus data element M′. Data points for a petroleum diesel sample, as well as B5, B20, B50, and B100 were plotted. The complex impedance values (Z*) is converted to a complex modulus representation (M*) in order to inversely weight and isolate the bulk capacitance value from any interfacial polarization present within the sample. The M′ high frequency intercept via a semicircular fitting routine is then calculated.

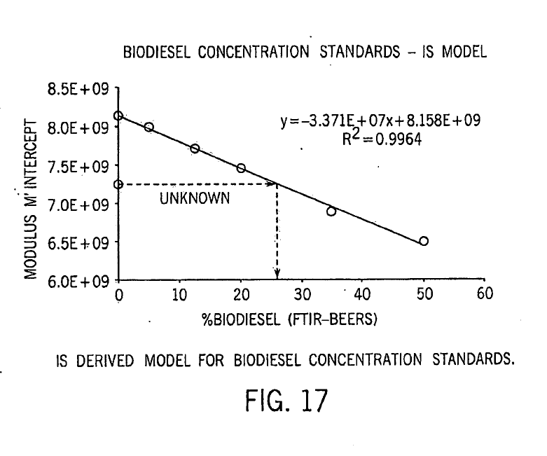

The biodiesel concentration standard, for which the impedance spectroscopy process will be measured against, is shown in FIG. 17. The previously calculated modulus (M′) intercept was plotted against the biodiesel concentration, as determined by the FTIR method. Equation Set 3 represents the derived algorithm.

y=−3.371E+07x+8.158E+09 Equation Set 3
where x=% biodiesel, and R²=0.9964

Biofuel samples are tested using the analyzer 12. The impedance data measurement is focused upon the biofuel sample while the electrode influence and probe fixturing are minimized.

In an alternative embodiment, fuel analyzer system 10 and methods of the present invention are used to determine the FAME concentration in heating fuel. The heating fuel sample is tested in a similar manner as that described for the biodiesel fuel blend. Alternatively, the system 10 can be used to analyze cutting fluids, engine coolants, heating oil (either petroleum diesel or biofuel) and hydrolysis of phosphate ester, which is used a hydraulic fluid (power transfer media).

In an alternative embodiment, the system 10 analyzes a biodiesel blend sample for the presence of substances selected from a group including second phase materials, fuel additives, glycerol, residual alcohol, moisture, unreacted feedstock (triacylglycerides), monglycerides, diglycerides, and free (unreacted) fatty acids. In yet another alternative embodiment, the system 10 analyzes a biodiesel blend sample for the concentration of substances selected from a group including second phase materials, fuel additives, methanol, glycerol, residual alcohol, moisture, unreacted feedstock (triacylglycerides), monoglycerides, diglycerides, and free (unreacted) fatty acids.

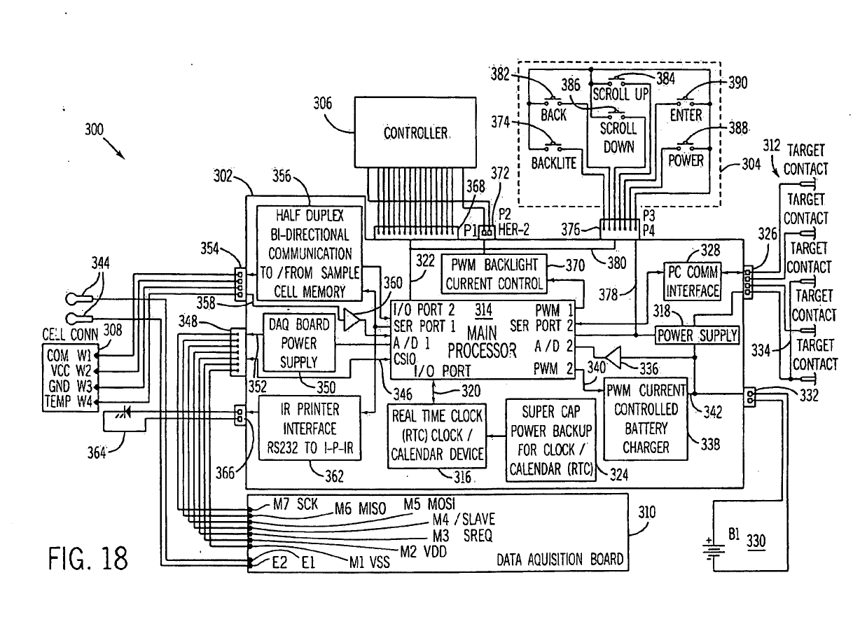

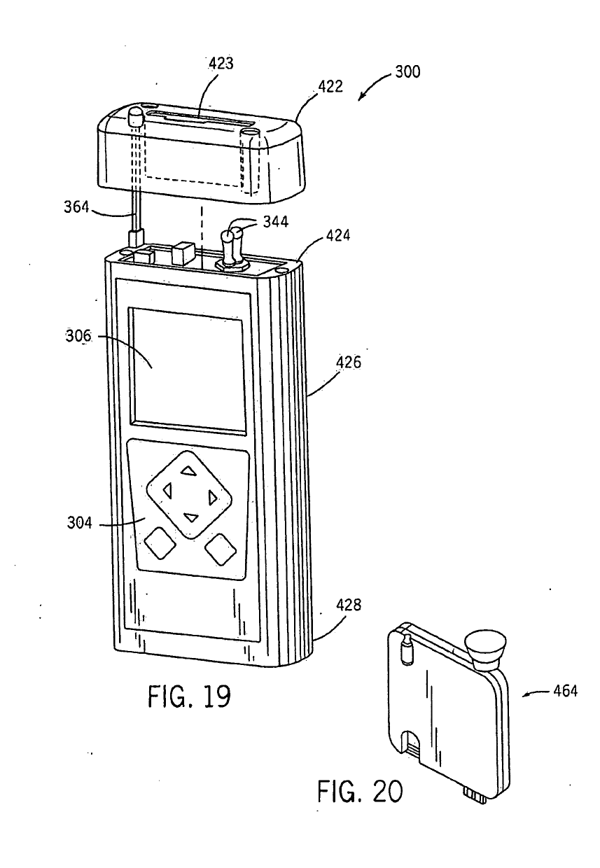

Another embodiment of an impedance spectroscopy system is illustrated in FIG. 19, which illustrates a perspective view of an exemplary hand-held impedance spectroscopy analysis device 300, which is operable with a sample cell, such as sample cell 464 illustrated in FIG. 20, to measure and analyze a fluid sample in accordance with impedance spectroscopy methods similar to those discussed above to determine one or more fluid properties. The sample cell serves as a reservoir for the fluid sample, and is preferably a one-time use detachable device that can be plugged into and removed from a slot 423 of the hand-held analysis device 300. The fluid sample is preferably a fuel sample such as a blended biofuel sample. The fluid properties which can be determined preferably include one or more of a biofuel (biodiesel) blend content or percentage, a total glycerin content or percentage, an acid number, and a methanol content or percentage. A block diagram of the hand-held analysis device 300 is illustrated in FIG. 18.

Referring to FIG. 18, the analysis device 300 includes a processing system 302 in operable association with a keypad 304, a display 306, a data acquisition board (DAQ board) 310, a light emitting diode (LED) 364, a battery 330, and a plurality of target contacts 312. The processing system 302 is also in communication with a cell connection unit 308 for connecting to the sample cell 464, which contains the fluid sample to be tested and analyzed. With respect to the processing system 302 in particular, it is capable of processing a wide variety of information received from one or more of the aforementioned components (e.g., keypad 304, the sample cell via connection unit 308, etc.) to determine fuel sample properties and display the same via the display 306. Each of the keypad 304, the display 306, the cell connection unit 308, the DAQ board 310, and the plurality of target contacts 312 are connected to the processing system 302 by way of one or more plugs (also referred herein as contacts, pins or connection points), as will be described in more detail below.

Further, as shown in FIG. 18, the processing system 302 includes a main processor 314 for processing various types of information; a real time clock (RTC)-calendar and clock device 316 for keeping track of current date and time; a power supply 318 for providing variable voltages to the various components of the hand-held analysis device 300; and a plurality of communication interfaces for connecting the components (through respective plugs) to the main processor, as well as other components. With respect to the RTC calendar and clock device 316, it is connected to the main processor 314 at a first Input/Output (I/O) port (e.g., I/O port 1) via duplex communication links 320 for providing continuous display of the current date and time on the display 306. Additionally, to accurately keep track of current date and time even when the hand-held analysis device 300 is powered off, the RTC calendar and clock device 316 is connected to a super cap power backup 324, which provides power to the RTC calendar and clock device when the hand-held device is turned off.

Power to the other components (e.g., keypad 304 and display 306) of the hand-held analysis device 300 is provided by the power supply 318. In particular, the power supply 318 receives a fixed voltage input and regulates the input voltage (in a known manner) to provide variable voltages for proper operation of the various components of device 300. Typically, the fixed voltage input power to the power supply 318 can be provided either via the target contacts 312 connected thereto through plugs 326 or through a battery 330 connected to the power supply through a plug 332. For example, a 12 Volt input from the target contacts 312 can be transformed into a 5 Volt power supply for powering the electronic circuitry of the main processor 314. Relatedly, a 3.3 Volt power supply can be generated for operation of the display 306. Similarly, variable voltages for the keypad 304, and other components of the hand-held analysis device 300 are generated from the power supply 318.

With respect to the target contacts 312, in addition to being connected to the power supply 318, the target contacts are also connected to the main processor 314 for duplex communication therewith. Particularly, the target contacts 312 are connected to the main processor 314 at a serial port (e.g., Ser Port 2) via a PC communication interface 328 connected to the plugs 326. By virtue of providing the target contacts 312 connected to the main processor 314 and the power supply 318, the hand-held analysis device 300 can be plugged into a charging base (not shown) and/or docking station (not shown) connected to a wall plug power supply (also not shown) for providing an input power to the power supply 318. When seated in the charging base (or docking station), the hand-held analysis device 300 can be used for viewing (e.g., on display 306) and/or transferring stored results and/or data from the main processor 314 to another device. Notwithstanding the fact that five target contacts are shown in the present embodiment, this number can vary in other embodiments as well.

The target contacts 312 are equipped with a safety/sensing mechanism for avoiding electrical shock to a user on contact with the target contacts. In at least some embodiments of the present invention, the target contacts are designed such that at least two of the target contacts are connected together to form a relay circuit. For example, as shown in the present embodiment, target contact 3 (TGT3) is connected to the target contact 5 (TGT 5) by communication link 334 to form a relay circuit. In normal operating conditions when the hand-held analysis device 300 is removed from the charging base, the relay circuit is broken and, therefore, no current flows through the target contacts, preventing electric shock to the user. Upon seating the hand-held analysis device 300 into the charging base, the relay circuit is closed by connection with the electrical contacts of the charging base and current flows through the target contacts for providing power to the power supply 318. Further, although in the present embodiment two target contacts are connected together to form the relay circuit, in other embodiments, more than two contacts can be connected together as well. Additionally, although one-exemplary safety/sensing mechanism for avoiding electric shock has been described above, it is nevertheless an intention of this invention to encompass other mechanisms as well.

In addition to employing the target contacts 312 for providing input power to the power supply 318, the hand-held analysis device 300 is also provided with the battery 330, which is preferably a rechargeable, replaceable battery connected to the power supply 318 of the processing system 302. The battery 330 is additionally connected to an analog-to-digital converter (e.g., A/D 2) port within the main processor 314 through an operational amplifier 336. By virtue of being connected to the power supply 318, the battery provides a source of input power for operating the hand-held analysis device 300 when the device is not seated in the charging base. This allows measurements from the fluid sample to be obtained, and processing performed, when the hand-held device 300 is operating in the battery mode.

As indicated above, the battery 330 is preferably a rechargeable battery that can be recharged upon seating the hand-held device 300 in the charging base. In particular, when the hand-held device 300 is seated in the charging base, and power is supplied from the power supply 318 to the main processor 314 (e.g., through the target contacts 312), the battery 330 is recharged by pulse width modulated (PWM) current controlled battery charger 338, connected on one end to a PWM port (e.g., PWM 2) of the main processor (e.g., by exemplary communication link 340), and on the other end to the battery (e.g., by communication link 342). In at least some embodiments of the present invention, the battery 330 is a 7.2 V Lithium-Ion (Li-Ion) battery, although other voltages and types of batteries are also contemplated.

Referring still to FIG. 18, the data acquisition board (DAQ Board) 310 is utilized for exciting electrodes 344 and acquiring measurement data indicative of the fluid sample. The acquired measurement data, for example magnitude and phase data at a predetermined set or plurality of frequencies, is then sent to the processing system 302 for analysis. Specifically, to obtain data from the fluid sample, the DAQ board 310, at contacts points E1 and E2, is connected to two electrodes 344 of the hand-held device 300. As explained more fully below, when the sample cell 464 is inserted in the hand-held device 300, the electrodes 344 are in contact with two metal plates of the sample cell, and the metal plates are in contact with the fluid sample in a reservoir formed between the metal plates in the sample cell. In at least some embodiments, the metal plates are arranged in a parallel plate electrode configuration, with a gasket between the metal plates. Thus, measurements corresponding to the fluid sample in the sample cell can be obtained by excitation of the electrodes 344 which contact the metal plates which contact the fluid sample in the sample cell.

In one embodiment, the DAQ board 310 is capable of providing a fixed excitation voltage to the electrodes 344, and measuring the current and phase angle of the fluid sample response relative to the excitation voltage. The process of applying an excitation voltage and measuring the resulting current and phase angle of the sample is repeated by varying the frequency of the voltage. For example, in at least some embodiments of the present invention, current and phase angle of the fluid sample relative to an excitation voltage can be measured for the predetermined plurality of frequencies, preferably approximately seven to ten different frequencies. In other embodiments, the number of and specific frequencies chosen can be varied. Further, in other embodiments for obtaining measurements, rather than applying a fixed excitation voltage, a fixed excitation current at varying frequencies can be applied and the resulting voltage and phase angle can be measured in at least some other embodiments for obtaining measurements. Also, the excitation voltage and/or excitation current need not be fixed. Rather, a varying current and/or voltage can be applied for exciting the fluid sample for data.

Subsequent to obtaining measurement data from the fluid sample, the DAQ board 310 communicates the sample measurement data to the main processor 314 for storage and processing. Particularly, the DAQ board 310 is connected to the main processor 314 at a CSIO port through a plug 348 and a duplex clocked (synchronous) serial I/O 346. Power to the DAQ board 310 is provided by the main processor 314 through a DAQ board power supply 350 connected at an analog-to-digital port (e.g., A/D 1) of the main processor. The DAQ board power supply 350 is additionally connected to the DAQ board 310 through the plug 348, as shown by a one-way communication link 352. By virtue of having a separate DAQ board power supply 350 for the DAQ board 310, power to the DAQ board can be turned off when the hand-held device 300 is not being used.

The main processor 314 is also in bi-directional communication with the sample cell when it is plugged into the hand-held device 300. In particular, a sample cell circuit (not shown) of the sample cell is connected, via cell connection unit 308, plug 354, and circuit 356, to main processor 314. The sample cell circuit includes a memory to store information such as an identifier and one or more calibration parameters relating to that sample cell. The sample cell memory is preferably a non-volatile memory capable of storing information even when the power to the sample cell is turned off. The memory is also preferably a memory which can be both read and written to. In at least some embodiments of the present invention, the memory can be configured as a removable memory device (e.g., a memory stick) that can be plugged and/or unplugged (e.g., via a Universal Serial Bus (USB) port) into the sample cell as desired.

In at least one embodiment, the sample cell memory can initially store a specific identifier, such as a serial number, which is unique to that sample cell. The main processor 314 is programmed to read the serial number and proceed with obtaining measurements only if that sample cell has not been previously used. In other words, the sample cell is a one-time use device, and re-use of the sample cell can be prevented.

Typically, the stored calibration parameters are also specific to the sample cell and relate to electrical characteristics of the dry (i.e. unfilled) sample cell, such as can be determined from impedance measurements of the dry sample cell at one or more frequencies. Thus, in addition to utilizing the measurement data corresponding to the fluid sample obtained by the DAQ board 310, the main processor 314 also reads the one or more calibration parameters from the sample cell memory and employs these parameters in the analysis of the fluid sample. Specifically, during operation, the one or more calibration parameters of the sample cell are provided to the main processor 314 via the cell connection unit 308, which is connected to the main processor via the plug 354 and half-duplex bi-directional communication interface 356. The half-duplex bi-directional communication interface 356 is additionally connected to the main processor 314 at a serial port (e.g., Ser Port 1) of the main processor.

In addition to calibration information, the main processor 314 preferably utilizes temperature information of the fluid sample in the determination of fluid sample properties, and produces results based upon the current temperature of the sample. Therefore, by virtue of determining the sample temperature and accounting for the temperature variations during processing, more accurate results can be obtained. In particular, temperature of the sample is obtained by a temperature sensor (not shown) provided on or within the sample cell. The temperature sensor determines the approximate current temperature of the fluid sample and transfers the temperature information through the cell connection unit 308 to the main processor 314. As shown, a separate voltage based temperature line 358 is connected to the A/D 1 port of the main processor 314 via an operational amplifier 360. Although, in the present embodiment, the A/D 1 port is connected to both the DAQ board power supply 350 and the voltage based temperature line 358, in alternate embodiments, separate analog-to-digital ports can be utilized.

Upon collection of the calibration and temperature information from the sample cell and magnitude and phase angle data from the sample fuel, the main processor 314 processes the information according to a stored algorithm, such as the algorithm explained above. In some embodiments, the processing system 302 and DAQ board 310 are programmed to determine one or more fluid sample properties using an improved algorithm which takes into account other variables, including for example the temperature of the sample and the calibration parameters mentioned above. Generally, such an improved algorithm can be developed using a data gathering technique in which a large set of data is gathered from various samples and then using a data mining technique to statistically analyze the data set, as more ftilly explained below.

Typically, the IR printer interface 362 employs a driver for converting RS232 ASCII code to the IR printer code, although other types of drivers can potentially be used. In at least some embodiments of the present invention, an HP 82240B IR printer available from the Hewlett-Packard Company of Palo Alto, Calif. is used. In alternate embodiments, printers other than the one mentioned above, can be used as well. Further, upon availability of results that can possibly be printed, the LED 364 is activated to signal to the printer the availability of the results. The photodiode is connected to the IR printer interface 362 via a plug 366. In addition to printing data on a printer, the present invention also provides the display 306, where results can alternatively be viewed.

With respect to the display 306, it is preferably a 128×128 pixel graphical LCD backlight display organized in eight lines of text, with each line capable of displaying 16 characters. In at least some embodiments, an Ampire Controller HD66750 display available from the Hitachi, Ltd of Marunouchi Itchome, Chiyoda, Tokyo, Japan can be used. The display 306 is connected to the main processor 314 by way a plug 368 connected to the I/O port 2 of the main processor. The intensity (e.g., brightness) of the display 306 can be manipulated by way of a pulse width modulated (PWM) backlight current control 370 connected to a pulse width modulated port (e.g., PWM 1) of the main processor 314. The (PWM) backlight current control 370 is connected to a plug 372 that further connects to a plurality of Light-Emitting-Diodes (LED) on the display 306. By virtue of altering the current by the PWM backlight current control 370, the intensity of the backlight of the display 306 can be altered.

Further, the display 306 can be maneuvered by way of the keypad 304, which is provided with a plurality of buttons that can be depressed to power on/off the hand-held device 300 from the battery mode and/or maneuver the display 306. To achieve such functionality, the keypad 304 is connected to the main processor 314 and the display 306. For example, by virtue of a plug 376, the keypad 304 is connected to the main processor 314 via a communication link 378, and to the display 306 via a communication link 380. The keypad 304 is provided with a plurality of buttons, including, for example, a “BACK LITE button 374 for turning on/off the backlight of the display 306, a “BACK” button 382 to return to a previous display, and “SCROLL UP” and “SCROLL DOWN” buttons 384 and 386, respectively, for moving the display up and down. Also provided is a “POWER” button 388 to turn on/off the hand-held device 300 from the battery mode and an “ENTER” button 390 to move a cursor on the display 306 and/or display a new value. Notwithstanding the fact that six buttons have been described above with respect to the keypad 304, additional buttons providing additional functionality are contemplated in alternate embodiments.

Referring again to FIG. 19, the hand-held analyzer device 300 includes a shroud assembly 422, a top cover assembly 424, a case assembly 426 and a bottom cover assembly 428. The shroud assembly 422 includes a slot 423 for receiving the sample cell 464. The case assembly 426 houses and protects many of the components shown in FIG. 18, including components such as the processing system 302 and the DAQ board 310 which are situated within the case assembly and components such as the display 306 and keypad 304 which are situated to be accessible to a user. The top cover assembly 424 acts as the interface between the sample cell and the processing system 302 and DAQ board 310, and includes the electrodes 344 which contact metal plates of the sample cell when the sample cell is inserted in the slot 423.

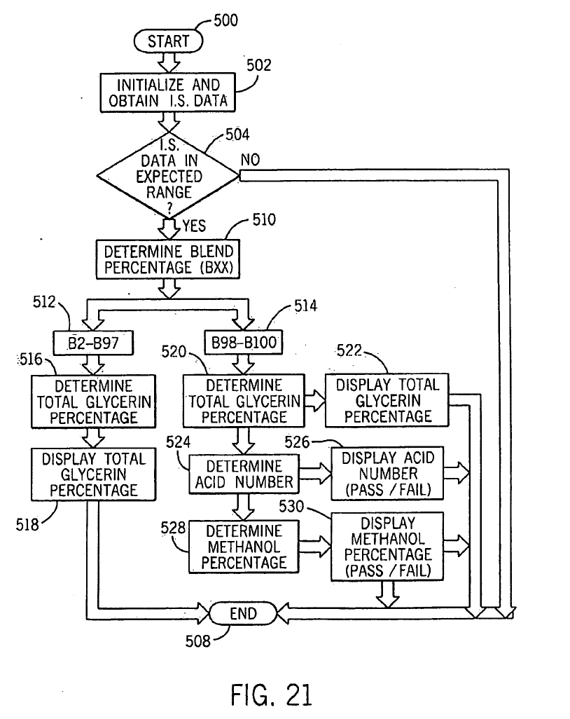

Referring now to FIG. 21, a flowchart is illustrated which shows exemplary steps of operation of the hand-held analysis device 300 for determining various properties or characteristics of a fluid sample such as a blended biofuel sample in accordance with at least some embodiments of the present invention. Operation begins at step 500. At step 502, initialization occurs and measurements are taken. In particular, the sample cell 464 is filled with the blended biofuel sample and inserted into the hand-held analysis device 300. The specific identifier corresponding to that sample cell and one or more calibration parameters stored in a memory (not shown) of the sample cell are downloaded to the processing system 302 of the hand-held device 300 by way of a plurality of communication links.

The processing system 302 then performs a check to ensure that the sample cell 464 has not previously been used. If the sample cell has not been previously used, operation can proceed; otherwise operation can be terminated. The calibration parameters can be evaluated to ensure that they are within respective predetermined ranges and/or additional measurements can be performed to measure these parameters and perhaps compare them to the initially stored parameters.

Next, measurements corresponding to the fluid sample can be obtained, including impedance values at the predetermined set of frequencies and one or more corresponding temperature measurements. Specifically, temperature measurements from a temperature sensor such as a thermistor in the sample cell are obtained and transmitted to the processing system 302. The biofuel sample is excited with a plurality of voltage signals at varying frequencies via the electrodes 344. A current response for each of the plurality of voltage signals is then measured and received by the DAQ board 310, then transmitted to the processing system 302 for processing. The measurement data sent from the DAQ board 310 to the processing system can be in “raw” form, including complex impedance magnitude and phase data at each of the frequencies in the predetermined plurality of frequencies.

At step 504, it is determined if the measured impedance data for the blended biofuel sample is within an expected range. Generally speaking, a variety of mechanisms, such as addition of additives, can cause the impedance data to go out of range. For example, addition of methanol to the fluid sample can increase the conductivity of the sample causing out of range impedance results. Thus, if it is determined at step 504 that the impedance results are out of range, the process then proceeds to step 508 and the process ends. In at least some embodiments, impedance results less than 1 mega-ohm (1MΩ) can be considered out of range. In other embodiments, other parameters for determining out of range data can be defined as well.

On the other hand, if at step 504 it is determined that the impedance data is indeed within the specified range, the process proceeds to a step 510. At step 510, a biofuel concentration within the fuel sample (e.g., biofuel blend percentage) is determined using an algorithm such as the algorithm described above with respect to FIGS. 1-17 which relates measured impedance data to a biofuel blend percentage, or preferably using an improved algorithm, such as that described below which is developed using a data gathering and data mining technique. The hand-held analysis device 300 is programmed to calculate this concentration in a Bxx format, where xx denotes the percentage of biofuel. Further, a variety of other properties or characteristics of the sample can also be determined depending upon the calculated concentration of biofuel within the sample.

For example, it can be determined whether the samples have biofuel concentration values in a first range (e.g., from B2 to B97) or in a second range (e.g., from B98 to B100). For samples having a biofuel concentration in the range from 2% to 97% (B2-B97), the process proceeds to step 512 and then step 516, where a total effective glycerin percentage of the sample can be calculated. In at least some embodiments, the total effective glycerin percentage can be determined by a glycerin algorithm for determining a glycerin percentage based on measured impedance spectroscopy data. This algorithm can also be developed using a data gathering and data mining technique. Subsequent to calculating the total effective glycerin percentage, the result is displayed at step 518 and the process ends at step 508.

Relatedly, if at step 510, a biofuel percentage of 98%-100% (B98-B100) within the sample is determined, the process proceeds to step 514. Next, at step 520, a glycerin analysis similar to the glycerin analysis performed at the step 516 for B2-B97 is performed for B98-B100, using a similar but different glycerin algorithm for determining a glycerin percentage based on measured impedance spectroscopy data. This second glycerin algorithm can also be developed using a data gathering and data mining technique. The result (e.g., the total effective glycerin percentage) is then displayed at step 522 and the process ends at step 508.

Further, in addition to determining the total effective glycerin percentage, various other properties of the sample fluid can be determined for sample fluids having a corresponding biodiesel concentration above a pretermined value, for example 98% and greater. In this case, at step 524, the total acid number of the biofuel sample can be determined. In at least some embodiments, the total acid number, which is a measure of the amount of carboxylic acid groups in a chemical compound, can be calculated using an acid number algorithm for determining an acid number based on measured impedance spectroscopy data. This acid number algorithm can also be developed using a data gathering and data mining technique. Subsequent to calculating the total acid number, the process proceeds to a step 526 for displaying the result of the calculation. Particularly, the result of the acid number determination, can be displayed in a variety of formats at the step 526. For example, in at least some embodiments, the acid number can be displayed in a pass/fail format. Specifically, a total acid number limit can be set such that a value beyond that limit is considered a “fail” and a value within that limit is considered a “pass.” In at least some embodiments, an acid number limit of 0.50 milligram Potassium Hydroxide/gram for biodiesel as set by EN14214 and ASTMD6751 standards can be employed. In other embodiments, other acid number limits can be pre-defined as well. Thus, the acid number determined at the step 524 is a “pass” if that acid number value is less than or equal to the 0.5 limit, or alternatively the acid number result is a “fail” if that value is greater than 0.5. Subsequent to displaying the result of the acid number at the step 526, the process ends at step 508.

Moreover, in addition to determining the glycerin percentage and the acid number of the sample fluid, a methanol percentage of the sample can be determined at a step 528. In at least some embodiments, the presence and concentration of methanol within the sample fluid can be calculated using a methanol percentage algorithm based on measured impendance spectroscopy data. This methanol percentage algorithm can also be developed using a data gathering and data mining technique. Furthermore, similar to the acid number, the results of methanol can be displayed in a variety of ways at a step 530. For example, the concentration of methanol can be displayed in a percentage format or alternatively in a pass/fail format in which methanol concentration above a pre-defined limit can be a “fail” and below that limit can be a “pass.” For the pass/fail format of displaying methanol concentration, in at least some embodiments a limit of 0.2% volume of methanol can be pre-defined. In other embodiments, other limits can be set as well. Subsequent to displaying the results of methanol at the step 530, the process proceeds and ends at the step 508.

Notwithstanding the fact that the total acid number and the methanol concentration are only determined for sample fluids having a concentration of greater than 98% biodiesel in the blended sample, it will be understood that those values can nevertheless be calculated and displayed for sample fluids having less than 98% biodiesel concentration. It will additionally be understood that although the acid number and methanol concentration for sample fluids with less than 98% biodiesel can be calculated, the acid number and the methanol percentage for B98-B100 is generally of greater interest, particularly given the relatively lower and potentially negligible values of the acid number and the methanol percentage of B2-B97 in comparison with the corresponding values for B98-B100.

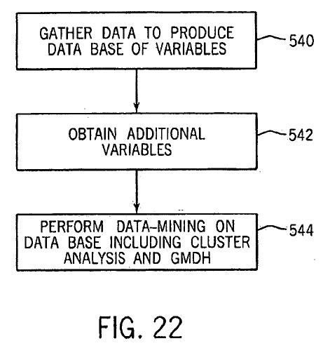

FIG. 22 is a flow chart illustrating an example general method for data gathering and data mining used to generate an algorithm for determining a desired fluid sample property using measured impedance spectroscopy data that is obtained using a device such as device 300. This general method can be used to ascertain an appropriate biofuel blend algorithm for determining an blended concentration based on measured IS data. This general method can also be used to ascertain an appropriate glycerin percentage algorithm for determining total glycerin percentage for biofuel samples having blended concentrations within a first specific range such as B2-B97 and to ascertain an appropriate glycerin percentage algorithm for determining total glycerin percentage for biofuel samples having blended concentrations within a second specific range such as B98-B100. This general method can also be used to ascertain an appropriate acid number algorithm for determining an acid number for a biofuel sample based on measured IS data; and to ascertain an appropriate methanol algorithm for determining a methanol percentage for a biofuel sample based on measured IS data.

The general method begins at step 540, at which data is gathered to produce a database. In particular, for each desired fluid sample property (blend concentration, glycerin concentration, etc.) a corresponding large sample set is tested. Each sample set includes a variety of compositions of the fluid property to be determined, and for each sample in a sample set, impedance spectroscopy data is obtained by measuring complex impedance values at each frequency in a given set of frequencies. In other words, each sample corresponds to an acquired data set with values for each of plurality of variables (magnitude and phase for each frequency). For each sample in a sample set, a corresponding analytical reference method other than impedance spectroscopy is used to measure the corresponding desired fluid sample property. For example, a blend concentration (B2-B99% volume) of each sample in a first sample set can be measured using a mid-infrared spectroscopy method, according to ASTM 7371 (ASTM stands for the American Society for Testing and Materials, which is an international standards organization that develops and publishes voluntary consensus technical standards for a wide range of materials, products, systems, and services). A total glycerin amount (0.03-0.7% m) of each sample in another sample set can be measured using a gas chromatography method, according to ASTM 6584 or SAFTEST, with a limit of 0.24% mass. An acid number (0.2-3.5 mg/KOH) of each sample in another sample set can be measured using a potentiometric titration, according to ASTM 664, with a limit of 0.5 mg/KOH. A methanol concentration (0.02-0.9% volume) of each sample in another sample set can be measured using a gas chromatography method, according to EN 14110, or mid infrared spectroscopy, with a limit of 0.2% volume.

At step 542, additional variables are obtained including one or more additional measured variables and additional calculated variables. One additional measured variable can be for example an associated temperature value for each sample. The additional calculated values are derived from the measured IS data set and its spectral structural features (i.e., the magnitude and phase data at different frequencies). Inverses of the variables can also be calculated.

At step 544, a data mining technique is employed. Data mining techniques can be used to uncover statistically significant variations in the electrical impedance data that correspond to changes in the physio-chemical measures of interest within the biofuel sample. The impedance data utilized can reflect biofuel bulk properties, as well as those derived from electro-active phenomena at the fuel/electrode interface. Such methods pair impedance information with the reference analytical values also obtained using the other methods, and apply various statistical techniques such as principal component analysis, multi-linear regression, principal components regression, or the application of non-linear neural network structures, in order to ascertain if meaningful correlations exist between the measured data and the physio-chemical property of interest. The latter approach can be employed using commercially available data mining software on the acquired data base, such as Knowledge Miner™ from Script Software, Inc.

In one embodiment, using the data mining software, cluster analysis is performed on the acquired variables to separate them into groups in order to eliminate co-variant or redundant variables. The reduced variable set is then paircd with known values of the physio-chemical property of interest, and modeled using a method known as “Group Method for Data Handling (GMDH)”. The resulting correlation is a multilayered neural network composed of connection weights that are polynomial (including linear) functions. This correlation provides the basis of a corresponding algorithm which the hand-held analysis device 300 is then programmed to perform.

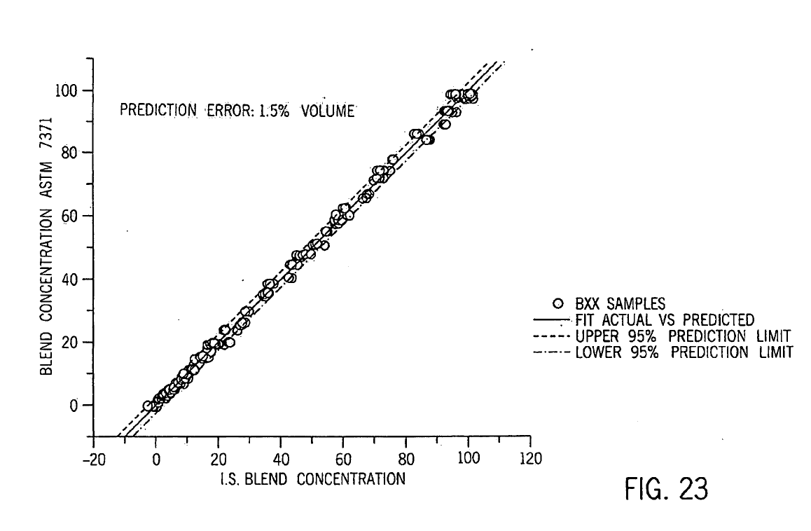

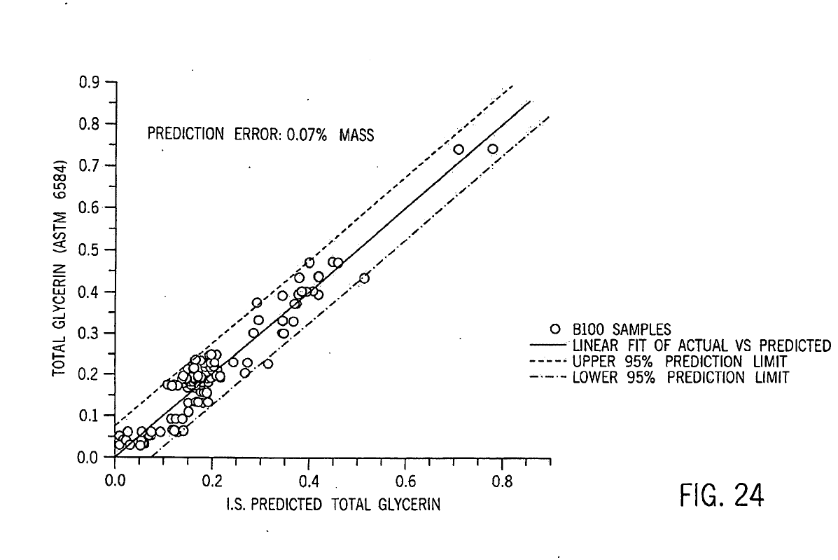

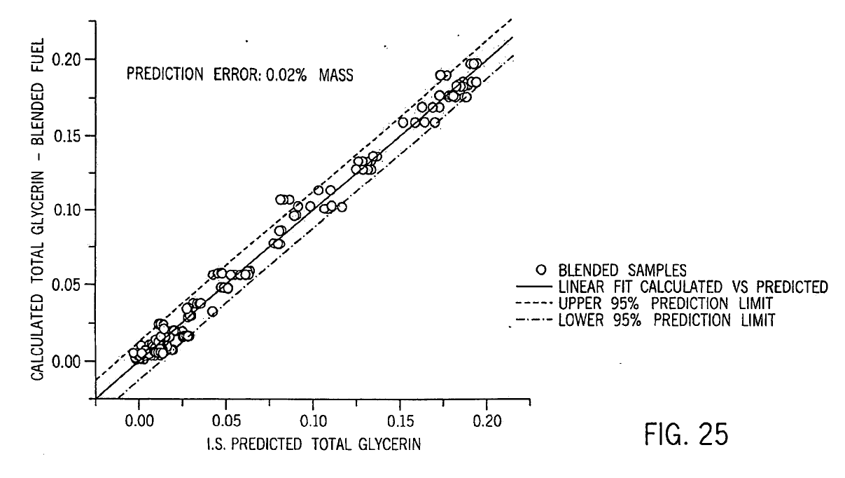

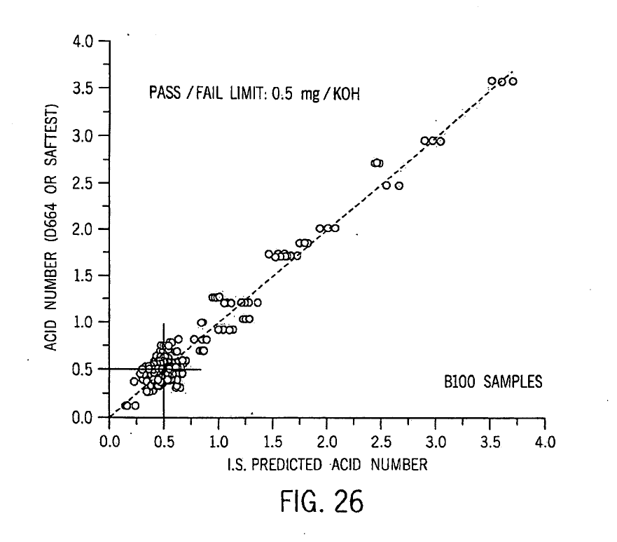

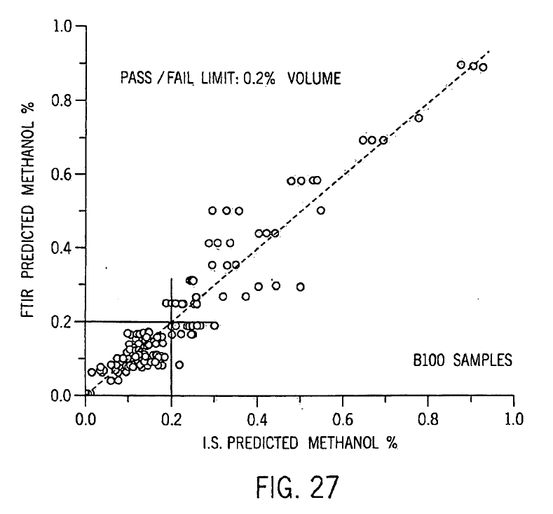

Correlations derived in this manner allow impedance spectroscopy to be implemented as an alternate screening method for biofuel blend verification, as illustrated in FIG. 23. Further, biodiesel fuel compliance with ASTM 6751 quality specifications for total glycerin, acid number and methanol content, can be determined either on a quantitative or pass/fail basis, as illustrated in FIGS. 24, 25, 26 and 27.

Any used sample cells 464 can be returned by a user to provide additional measured data. Any fluid sample remaining in the sample cell can be further tested. This result, along with the measurement data stored in the sample cell, can be added to the gathered data set, and additional data mining can be performed to further refine and fine-tune one or more algorithms for determining one or more respective fluid properties.

Notwithstanding the embodiment of the hand-held analysis device 300 described above, additions and/or refinements to the device are contemplated. For example, although the main processor 314 has been explained with respect to specific functionality, it can be appreciated that the main processor is capable of performing a wide variety of additional operations other than those described above. Further, the type, model and specifications of the various components of the hand-held device can vary from one embodiment to another. Additionally, the communication interfaces and connections with respect to the various components described above are exemplary and as such variations are contemplated and considered within the scope of the present invention. Components other than described above can also be used in conjunction with the device 300. The shapes, sizes, material of construction and the orientation of the various components described above can vary depending upon the embodiment. Further, despite any method(s) being outlined in a step-by-step sequence, the completion of acts or steps in a particular chronological order is not mandatory. Any modification, rearrangement, combination, reordering, or the like, of acts or steps is contemplated and considered within the scope of the description and claims. It is specifically intended that the present invention not be limited to the embodiments and illustrations contained herein, but include modified forms of those embodiments including portions of the embodiments and combinations of elements of different embodiments.

The following United States patent documents are hereby incorporated by reference in their entirety herein. U.S. Pat. No. 6,278,281; U.S. Pat. No. 6,377,052; U.S. Pat. No. 6,380,746; U.S. Pat. No. 6,839,620; U.S. Pat. No. 6,844,745; U.S. Pat. No. 6,850,865; U.S. Pat. No. 6,989,680; U.S. Pat. No. 7,043,372; U.S. Pat. No. 7,049,831; U.S. Pat. No. 7,078,910; U.S. Patent Appl. No. 2005/0110503; and U.S. Patent Appl. No. 2006/0214671.

Although the invention has been described in detail with reference to preferred embodiments, variations and modifications exist within the scope and spirit of the invention as described and defined in the following claims.

What is claimed is:

1. A method for determining two or more properties of a blended biofuel fluid sample, the method comprising:
measuring a complex impedance of the sample at each of a plurality of frequencies to produce a sample data set;
determining a biofuel blend percentage of the sample using the sample data set; and
determining at least one additional property of the sample based upon the determined biofuel blend percentage.

2. The method of claim 1, wherein the at least one additional property of the sample includes one property selected from the group including total glycerin percentage, acid number, and methanol content.

3. The method of claim 1, wherein the at least one additional property of the sample includes one property selected from the group including total glycerin percentage, acid number above or below a predetermined acid number value, and a methanol percentage above or below a predetermined methanol percentage value.

4. The method of claim 3, further including displaying one or more of the determined properties on a hand-held impedance spectroscopy device.

5. The method of claim 1, wherein a total glycerin percentage is determined when the biofuel blend percentage within a first range and a total glycerin percentage and one or more additional properties are determined when the biofuel blend percentage is within a second range.

6. The method of claim 5, wherein the first range is from B2 to B97.

7. The method of claim 5, wherein the second range is from B98 to B100.

8. The method of claim 1, wherein the biofuel blend percentage of the sample is determined if the impedance spectroscopy data is within an expected range.

9. A method for determining a biofuel blend percentage of a blended biofuel fluid sample, the method comprising:
measuring a complex impedance of the sample at each of a plurality of frequencies to produce a sample data set;
determining a biofuel blend percentage of the sample using the sample data set and an algorithm developed using a data gathering and data mining technique relating measured impedance spectroscopy data from a plurality of samples to biofuel blend percentage values determined using a standard analytical measuring method for biofuel blend percentages.

10. The method of claim 9 further including determining at least one additional property of the sample based upon the determined biofuel blend percentage and using a second algorithm developed using a data gather and data mining technique relating measured impedance spectroscopy data from a plurality of samples to property values determined using another analytical measuring method for that property value.

11. The method of claim 10, wherein the at least one additional property of the sample includes one property selected from the group including total glycerin percentage, acid number, and methanol content.

12. The method of claim 10, wherein the at least one additional property of the sample includes one property selected from the group including total glycerin percentage, acid number above or below a predetermined acid number value, and a methanol percentage above or below a predetermined methanol percentage value.

13. The method of claim 12, further including displaying one or more of the determined properties on a hand-held impedance spectroscopy device.

14. The method of claim 10, wherein a total glycerin percentage is determined when the biofuel blend percentage within a first range and a total glycerin percentage and one or more additional properties are determined when the biofuel blend percentage is within a second range.

15. The method of claim 14, wherein the first range is from B2 to B97.

16. The method of claim 14, wherein the second range is from B98 to B100.

17. The method of claim 9, wherein the biofuel blend percentage of the sample is determined only if the impedance spectroscopy data is within an expected range.
